(19) United States
(12) Patent Application Publication
(10) Pub. No.: US 2022/0037563 A1
(43) Pub. Date: Feb. 3, 2022

(54) LATERAL LIGHT EMITTING DEVICE PACKAGE

(71) Applicant: BLOOMING INTERNATIONAL LIMITED, British West Indies (AI)

(72) Inventor: Shu-Fa SHAO, Taipei (TW)

(21) Appl. No.: 17/155,708

(22) Filed: Jan. 22, 2021

(30) Foreign Application Priority Data
Jul. 31, 2020 (CN) 202010759597.3

(51) Int. Cl. H01L 33/48; H01L 25/13; H01L 33/54; H01L 33/62

(52) U.S. Cl. CPC H01L 33/486; H01L 33/62; H01L 33/54; H01L 25/13

(57) ABSTRACT

A lateral light emitting device package includes an electrically-insulated substrate, a first and a second mounting pad, an LED chip and a transparent material. The first and second mounting pads cover first and second lateral surfaces of the electrical-insulated substrate, and the first and second mounting pads cover a top and bottom surfaces of the electrically-insulated substrate. First and second gaps are respectively defined between the first and second mounting pads. The LED chip is mounted on the first mounting pad and corresponding to the top surface. A first electrode and a second electrode of the LED chip are electrically connected to the first and the second mounting pads respectively. The transparent material is disposed corresponding to the top surface, partially covers the first and the second mounting pads, wraps the LED chip, and fills the first gap.

### CROSS-REFERENCE TO RELATED APPLICATIONS

This non-provisional application claims priority under 35 U.S.C. § 119(a) to China Patent Application No. 202010759597.3 filed, Jul. 31, 2020, the entire contents of which are hereby incorporated by reference.

### FIELD OF THE INVENTION

This disclosure relates to an optoelectronic device, and in particular, to a lateral light emitting device package.

### BACKGROUND

A light emitting diode is a solid-state optoelectronic device configured to transform electricity into luminous energy. The light emitting diode includes a semiconductor chip. A negative electrode of the chip is connected to a metal frame, the positive electrode of the chip is connected to a power supply pin, and the chip is completely wrapped by epoxy resins. The LED chip includes a P-type semiconductor and an N-type semiconductor. When currents applied to the chip via bonding wires, the chip illuminates. The LED chip requires protection, so as to keep away from dust and dirt, humidity, electrostatic discharge (ESD) and mechanical disruption. When applying currents, heat generated in the P-N semiconductors has to be removed to prevent the light emitting diode from being overheated. In the art various materials and package structures are developed to remove heat generated by the light emitting diode.

FIG. 1, FIG. 2, and FIG. 3 show a light emitting diode package 1 in the art, wherein FIG. 1 is a front view, FIG. 2 is a top view, and FIG. 3 is a bottom view. As shown in the drawings, the light emitting diode package 1 includes a printed circuit board 2, an LED chip 3, a first bonding wire 4, a second bonding wire 5, and a molded glue bulk 6. A chip bonding pad 2c and a wire bonding pad 2d are disposed on a top surface of the printed circuit board 2, and two mounting pads 2e are disposed on a bottom surface of the printed circuit board 2. The LED chip 3 is mounted on the chip bonding pad 2c. The first bonding wire 4 and the second bonding wire 5 respectively connect two electrodes of the LED chip to the chip bonding pad 2c and the wire bonding pad 2d. The molded glue bulk 6, of epoxy resins or silicon, is molded to wrap the LED chip 3, the first bonding wire 4 and the second bonding wire 5, so as to protect the light emitting diode 3.

FIG. 4, FIG. 5, and FIG. 6 show the light emitting diode package 1 soldered onto two metal wires 200. The metal wire 200 can be a bare wire, or the exposed part of an enameled wire or a plastic coated wire. The two metal wires 200 are respectively welded to the two mounting pads 2e. Through the first bonding wire 4, the second bonding wire 5, the chip bonding pad 2c, and the wire bonding pad 2d, electricity is provided to the LED chip 3 and the LED chip 3 illuminates.

As shown in FIG. 5 and FIG. 6, observing in the top view or the bottom view when the LED chip 3 illuminates only one side (the side in the top view) of the package reveals the LED chips illuminating well, and the other side (the side in the bottom view) reveals that the LED chip 3 and the molded glue bulk 6 are shielded by the printed circuit board 2. Therefore, the light emitting diode package 1 can only illuminate light in an angle less than 180 degrees.

### SUMMARY

In view of the above problem, this disclosure provides a lateral light emitting device package to solve the problems in the art.

At least one embodiment of this disclosure provides a lateral light emitting device package including an electrically-insulated substrate, a first mounting pad, a second mounting pad, and an LED chip. The electrically-insulated substrate includes a top surface, a bottom surface, a first lateral surface and a second lateral surface. The first lateral surface and the second lateral surface are arranged opposite to each other, and the first lateral surface and the second lateral surface connect the top surface to the bottom surface. The first mounting pad covers the first lateral surface, and the second mounting pad covers the second lateral surface. The first mounting pad and the second mounting pad cover the top surface and a first gap is defined between the first mounting pad and the second mounting pad, and the first mounting pad and the second mounting pad cover the bottom surface and a second gap is defined between the first mounting pad and the second mounting pad. The LED chip is mounted on the first mounting pad and corresponding to the top surface. A first electrode and a second electrode of the LED chip are electrically connected to the first and the second mounting pads respectively. The molded glue bulk is disposed corresponding to the top surface, partially covers the first and the second mounting pads, wraps the LED chip, and fills the first gap.

In at least one embodiment, providing a height direction defined as a direction from the top surface to the bottom surface the molded glue bulk has a glue thickness in the height direction, the electrically-insulated substrate has a substrate thickness in the height direction, and the glue thickness is larger than the substrate thickness.

In at least one embodiment, the glue thickness is larger than twice the substrate thickness.

In at least one embodiment, providing a length direction defined as a direction from the first lateral surface to the second lateral surface and in perpendicular to the height direction, and providing a width direction in perpendicular to the height direction and the length direction, a substrate length of the electrically-insulated substrate in the length direction is larger than a substrate width of the electrical-insulated substrate in the width direction.

In at least one embodiment, the substrate length is larger than triple the substrate width.

In at least one embodiment, in the width direction, a glue width of the molded glue bulk is equal to the substrate width.

In at least one embodiment, in the width direction, a pad width of each of the first mounting pad and the second mounting pad is equal to the substrate width.

In at least one embodiment, the lateral light emitting device package further includes a first bonding wire and a second bonding wire, wherein the first bonding wire is connected to the first electrode and the first mounting pad, and the second bonding wire is connected to the second electrode and the second mounting pad.

In at least one embodiment, the lateral light emitting device package further includes two metal wires arranged in parallel to the height direction; wherein portions, of the first mounting pad and the second mounting pad, corresponding to the top surface and the bottom surface are respectively soldered to the two metal wires.

In at least one embodiment, the molded glue bulk is located between the two metal wires.

In one or some embodiments of this disclosure, the glue thickness of the molded glue bulk is arranged to make the molded glue bulk significantly protrude from the electrically-insulated substrate. Therefore, observing in the top view or the bottom view of the metal wires the molded glue bulk in this disclosure is larger than the molded glue bulk in the art, and provides a large illumination surface, thereby providing good illumination performance. Meanwhile, this disclosure reduces the substrate width of the electrical-insulated substrate, so as to significantly reduce a shielding effect of the electrically-insulated substrate and make the lateral light emitting diode package illuminate light in almost 360 degrees.

### BRIEF DESCRIPTION OF THE DRAWINGS

This disclosure will become more fully understood from the detailed description given herein below for illustration only, and thus not limitative of this disclosure, wherein:

FIG. 1 is a front view of a light emitting diode package in the art.

FIG. 2 is a top view of the light emitting diode package in the art.

FIG. 3 is a bottom view of the light emitting diode package in the art.

FIG. 4 is a front view of the light emitting diode package soldered onto two metal wires in the art.

FIG. 5 is a top view of the light emitting diode package soldered onto two metal wires in the art.

FIG. 6 is a front view of the light emitting diode package soldered onto two metal wires in the art.

FIG. 7 is a front view of a lateral light emitting diode package according to an embodiment of this disclosure.

FIG. 8 is a top view of the lateral light emitting diode package according to the embodiment of this disclosure.

FIG. 9 is a bottom view of the lateral light emitting diode package according to the embodiment of this disclosure.

FIG. 10 is a bottom view of the lateral light emitting diode package soldered onto two metal wires according to the embodiment of this disclosure.

FIG. 11 is a front view of the lateral light emitting diode package soldered onto two metal wires according to the embodiment of this disclosure.

FIG. 12 is a rear view of the lateral light emitting diode package soldered onto two metal wires according to the embodiment of this disclosure.

FIG. 13 is a front view of the light emitting diode package soldered onto two metal wires according to another embodiment of this disclosure.

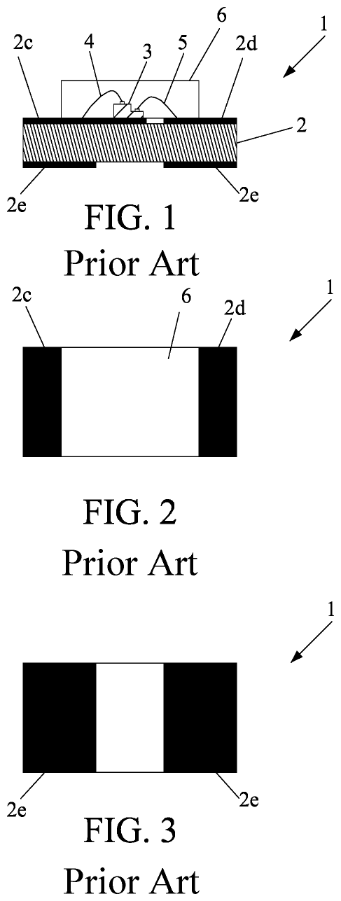

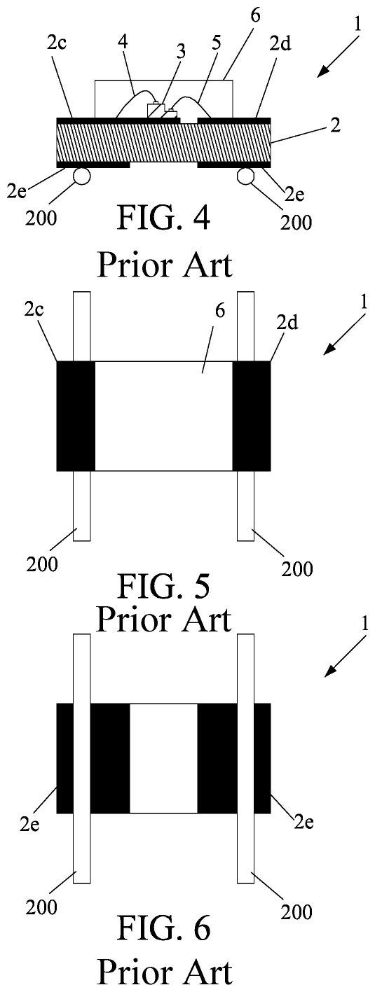

### DETAILED DESCRIPTION

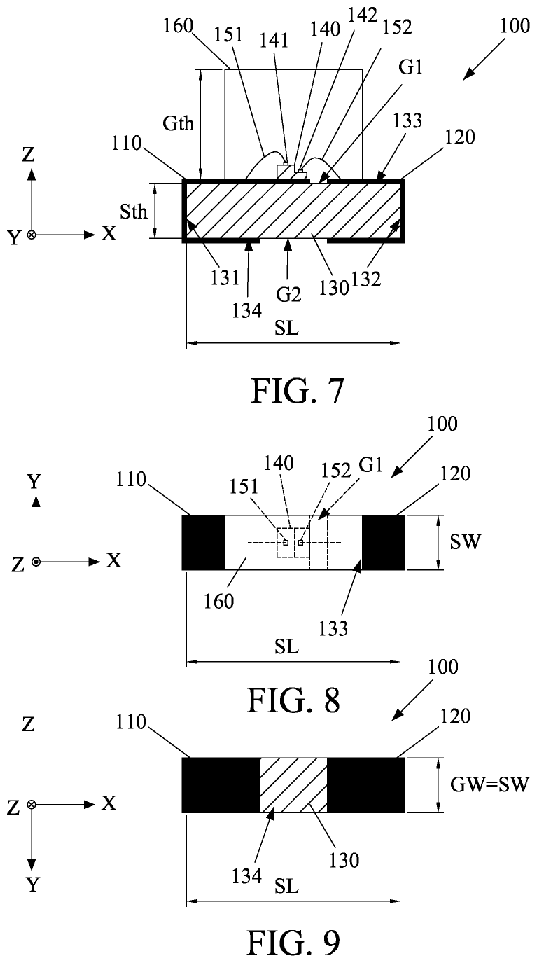

Referring to FIG. 7, FIG. 8, and FIG. 9, a lateral light emitting device package 100 according to an embodiment of this disclosure is shown. The lateral light emitting device package 100, which also may be referred to as an LED assembly 100 or lamp 100, includes an electrical-insulated substrate 130, a first mounting pad 110, a second mounting pad 120, an LED chip 140, a first bonding wire 151, a second bonding wire 152, and a molded glue bulk 160. The molded glue bulk 160 or glue material 160 in an embodiment comprises a transparent or translucent material, such as, but not limited to, an epoxy resin.

As shown in FIG. 7, FIG. 8, and FIG. 9, the electrical-insulated substrate 130 is used to provide electrical insulation. In one specific embodiment, the combination of the electrically-insulated substrate 130, the first mounting pad 110 and the second mounting pad 120 is a printed circuit board. Namely, through the manufacturing of the printed circuit board, the electrically-insulated substrate 130, the first mounting pad 130, and the second mounting pad 120 are manufactured at once. In some embodiments, the electrically-insulated substrate 130 is a metal substrate with a surface insulation treatment, or an electrically-insulated ceramic substrate. The aforementioned metal substrate or ceramic substrate provide good heat conduction and heat dissipation effects.

As shown in FIG. 7, the electrically-insulated substrate 130 includes a top surface 133, a bottom surface 134, a first lateral surface 131, and a second lateral surface 132. The first lateral surface 131 and the second lateral surface 132 are arranged opposite to each other, and the first lateral surface 131 and the second lateral surface 132 connect the top surface 133 to the bottom surface 134.

As shown in FIG. 7, FIG. 8, and FIG. 9, the first mounting pad 110 and the second mounting pad 120 cover the first lateral surface 131 and the second lateral surface 132 respectively. In an embodiment, surfaces 131 and 132 are completely covered, in other embodiments surfaces 131 and 132 are partially covered by the mounting pads 110 and 120. Meanwhile, the first mounting pad 110 and the second mounting pad 120 extend to the top surface 133 and the bottom surface 134. The first mounting pad 110 and the second mounting pad 120 cover portions of the top surface and a first gap G1 is defined between the first mounting pad 110 and the second mounting pad 120, and the first mounting pad 110 and the second mounting pad 120 cover the bottom surface and a second gap G2 is defined between the first mounting pad 110 and the second mounting pad 120.

As shown in FIG. 7, FIG. 8, and FIG. 9, the first mounting pad 110 provides a bonding position, and the bonding position corresponds to the top surface 133. The LED chip 140 is disposed at the bonding position, that is, the LED chip 140 is mounted on the first mounting pad 110, and corresponding to the top surface 133. The LED chip 140 includes a first electrode 141 and a second electrode 142 electrically connected to the first mounting pad 110 and the second mounting pad 120 respectively, so as to electrically connect the LED chip 140 to the first mounting pad 110 and the second mounting pad 120.

As shown in FIG. 7 and FIG. 8, the lateral light emitting device package 100 further includes a first bonding wire 151 and a second bonding wire 152. The first bonding wire 151 is connected to the first electrode 141 and the first mounting pad 110, and the second bonding wire 152 is connected to the second electrode 142 and the second mounting pad 120.

As shown in FIG. 7 and FIG. 8, the molded glue bulk 160 is disposed corresponding to the top surface 133, and partially covers the first mounting pad 110 and the second mounting pad 120. Portions, of the first mounting pad 110 and the second mounting pad 120, corresponding to the first lateral surface 131 and the second lateral surface 132 are exposed from, or not covered by, the molded glue bulk 160. The molded glue bulk 160 wraps or covers the LED chip 140, the first bonding wire 151, and the second bonding wire 152, and fills the first gap G1.

As shown in FIG. 7, FIG. 8, and FIG. 9, providing a height direction Z defined as a direction from the top surface 133 to the bottom surface 134, the molded glue bulk 160 has a glue thickness Gth in the height direction Z, the electrically-insulated substrate 130 has a substrate thickness Sth in the height direction Z, and the glue thickness Gth is larger than the substrate thickness Sth. The glue thickness Gth is larger than twice the substrate thickness Sth. Providing a length direction X defined as a direction from the first lateral surface 131 to the second lateral surface 132 and in perpendicular to the height direction Z, and providing a width direction Y in perpendicular to the height direction Z and the length direction X, a substrate length SL of the electrical-insulated substrate 130 in the length direction X is larger than a substrate width SW of the electrical-insulated substrate 130 in the width direction Y. The substrate length SL is larger than triple the substrate width SW. In addition, in one embodiment, in the width direction Y, a glue width GW of the molded glue bulk 160 is equal to the substrate width SW. In the width direction Y, a pad width of each of the first mounting pad 110 and the second mounting pad 120 is equal to the substrate width SW. Namely, in the width direction Y, the first mounting pad 110 and the second mounting pad 120 fully cover the top surface 133, cover the top surface 133 in the length direction X together and keep the first gap G1.

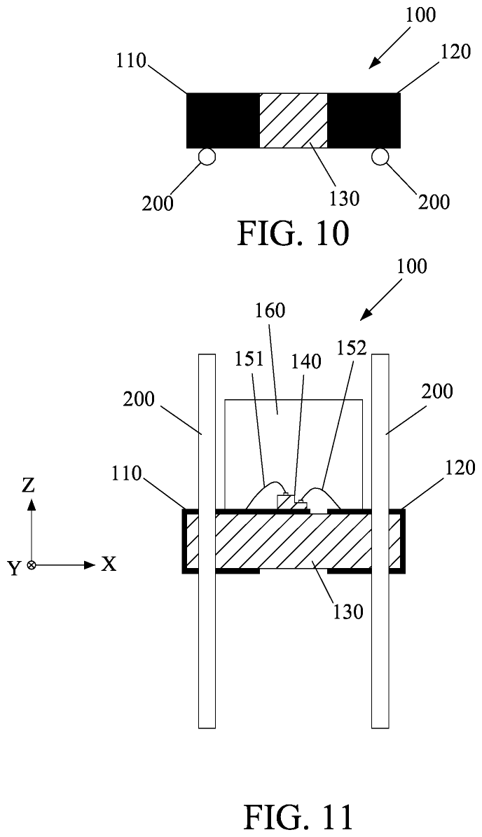

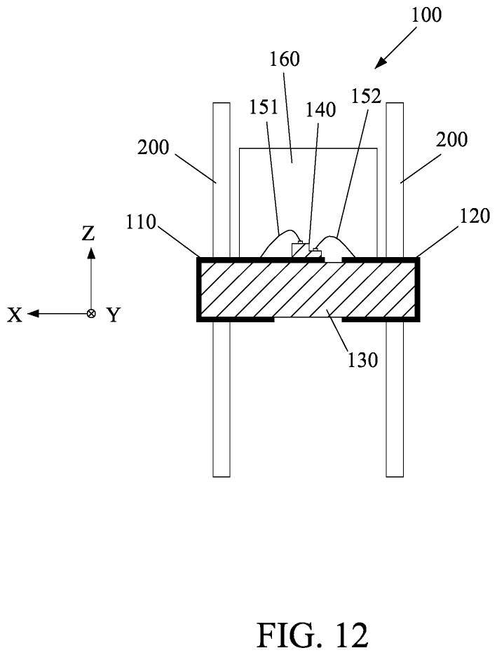

Referring to FIG. 10, FIG. 11, and FIG. 12, the lateral light emitting device package 100 further includes two metal wires 200. The metal wire 200 can be a bare wire, or the exposed part of an enameled wire or a plastic coated wire. The two metal wires 200 are arranged in parallel to the height direction Z. Portions, of the first mounting pad 110 and the second mounting pad 120, corresponding to the top surface and the bottom surface are respectively soldered to the two metal wires 200. The lateral light emitting device package 100 is laterally soldered to the two metal wires 200 with the molded glue bulk 160 protruding in a direction in parallel to the extension direction of the metal wires 200. The metal wires 200 contact and connect the first mounting pad 110 and the second mounting pad 120 at edges of the top surface 133 and bottom surface 134. Through the solder connection the metal wires 200 are electrically connected to the first mounting pad 110 and the second mounting pad 120. The molded glue bulk 160 is located between the two metal wires 200. In an embodiment, the glue bulk 160 extends beyond the two metal wires 200.

Through the connection of the first bonding wire 151, the second bonding wire 152, the first mounting pad 110 and the second mounting pad 120, the metal wires 200 are able to provide electricity to the LED chip 140, and the LED chip 140 illuminates. Usually the metal wire 200 is a copper wire, and wires made of another metal having high conductivity are not excluded. Provided a plurality of lateral light emitting device package 100 soldered onto the two metal wires 200 in sequence, a light string that illuminates light in a plurality of directions is obtained.

As shown in FIG. 11 and FIG. 12, applying electricity to the first electrode 141 and the second electrode 142 via the two metal wires 200, the LED chip 140 illuminates. Viewing the lateral light emitting device package 100 in top view or bottom view of the two wires, the LED chip 140 illuminates light laterally (illuminates in the height direction Z). Meanwhile, the molded glue bulk 160 protrudes laterally (protrudes in the height direction Z), the light guide effect of the molded glue bulk 160 will not be shielded in the length direction X or the width direction Y, and lateral light emitting device package 100 provides a good luminous effect in the length direction X and the width direction Y. The molded glue bulk 160 protruding in the height direction Z can also reduce the degree of light shielding by the electrically-insulated substrate 130, such that the lateral light emitting device package 100 illuminates light within an angle in approximately 360 degrees. Particles, such as fluorescent particles, reflective particles, or dye particles, can be added into the molded glue bulk 160 to change illumination characteristics.

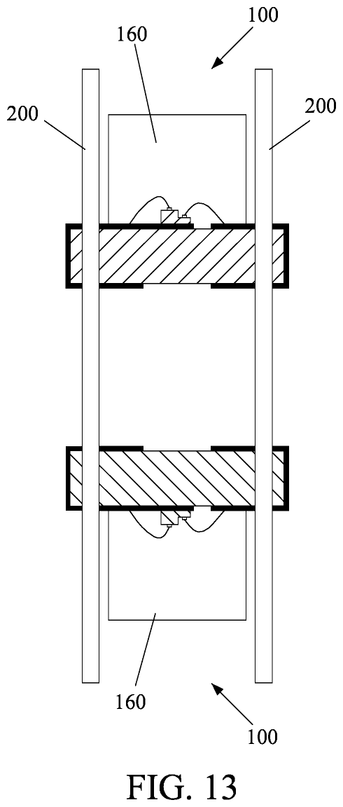

Referring to FIG. 13, in an embodiment, a plurality of lateral light emitting device packages or lamps 100 are soldered onto the two metal wires 200, in each pair of the lateral light emitting device packages 100 the molded glue bulks 160 protrude in opposite directions, to make the two lateral light emitting diode packages 100 illuminate light in almost 360 degrees.

In one or some embodiments of this disclosure, the glue thickness of the molded glue bulk 160 is arranged to make the molded glue bulk 160 significantly protrude from the electrical-insulated substrate 130. Therefore, observing in the top view or the bottom view of the metal wires 200, the molded glue bulk 160 in this disclosure is larger than the molded glue bulk in the art, and provides a larger illumination surface, thereby providing good illumination performance. Meanwhile, this disclosure reduces the substrate width SW of the electrical-insulated substrate 130, so as to significantly reduce a shielding effect of electrically-insulated substrate 130 to make the lateral light emitting diode package illuminate light in almost 360 degrees.

1.-10. (canceled)

11. A light string, comprising:
a first wire;
a second wire extending parallel to the first wire;
a plurality of light-emitting diode (LED) assemblies electrically connected to the first wire and the second wire, each of the plurality of LED assemblies including:
a substrate, including a top surface, a bottom surface, a first lateral surface, and a second lateral surface, wherein the first lateral surface and the second lateral surface are arranged opposite to each other;
a first mounting pad, covering at least a portion of the first lateral surface;
a second mounting pad, covering at least a portion of the second lateral surface, wherein the first mounting pad and the second mounting pad cover a portion of the top surface and a first gap is defined between the first mounting pad and the second mounting pad at the top surface, and the first mounting pad and the second mounting pad cover a portion of the bottom surface and a second gap is defined between the first mounting pad and the second mounting pad at the bottom surface;
an LED chip, mounted on the first mounting pad on the top surface; wherein a first electrode and a second electrode of the LED chip are electrically connected to the first mounting pad and the second mounting pad respectively; and
a transparent material partially covering the first mounting pad and the second mounting pad, covering the LED chip, and filling the first gap
wherein the first wire is in connection with the first mounting pad at an edge of a top surface of the first mounting pad and at an edge of a bottom surface of the first mounting pad, and second wire is in connection with the second mounting pad at an edge of a top surface of the second mounting pad and at an edge of a bottom surface of the second mounting pad.

12. The light string of claim 11, wherein the transparent material comprises a glue material.

13. The light string of claim 11, wherein the transparent material comprises an epoxy resin material.

14. The light string of claim 11, wherein the top surface faces a direction parallel to the first wire and the second wire.

15. The light string of claim 11, wherein a height direction is defined as a direction from the top surface to the bottom surface, the transparent material has a thickness in the height direction, the electrically-insulated substrate has a substrate thickness, and the transparent material thickness is larger than the substrate thickness.

16. The light string of claim 15, wherein the transparent material thickness is larger than twice the substrate thickness.

17. The light string of claim 15, wherein a length direction is defined as a direction from the first lateral surface to the second lateral surface and perpendicular to the height direction, and a width direction is perpendicular to the height direction and the length direction, a substrate length of the electrically-insulated substrate in the length direction is larger than a substrate width of the electrically-insulated substrate in the width direction.

18. The light string according to claim 17, wherein the substrate length is larger than triple the substrate width.

19. The light string according to claim 17, wherein in the width direction, a glue width of the glue material is equal to the substrate width.

20. The light string according to claim 17, wherein in the width direction, a pad width of each of the first mounting pad and the second mounting pad is equal to the substrate width.

21. The light string of claim 11, wherein a portion of the mounting pad is located between the edge of the top surface of the first mounting pad and the edge of the bottom surface of the first mounting pad.
